(19) United States
(12) Patent Application Publication
(10) Pub. No.: US 2025/0151598 A1
(43) Pub. Date: May 8, 2025

(54) METHOD FOR MANUFACTURING LIGHT-EMITTING ELEMENT, METHOD FOR MANUFACTURING DISPLAY PANEL, AND DISPLAY PANEL

(71) Applicant: HKC CORPORATION LIMITED, Shenzhen (CN)

(72) Inventors: YAO LI, Shenzhen (CN); Lidan YE, Shenzhen (CN)

(21) Appl. No.: 18/938,332

(22) Filed: Nov. 6, 2024

(30) Foreign Application Priority Data
Nov. 7, 2023 (CN) 202311470186.2

(51) Int. Cl. H10K 71/15; B82Y 35/00; B82Y 40/00; H10K 71/40

(52) U.S. Cl. CPC H10K 71/15; B82Y 35/00; H10K 71/40; B82Y 40/00

(57) ABSTRACT

A method for manufacturing a light-emitting element, a display panel, and a display panel are disclosed. The manufacturing method includes: forming multiple hollow nanospheres of various weights, the hollow nanospheres being filled with respective light-emitting materials; disposing the hollow nanospheres on a substrate; performing screening so that the hollow nanospheres are stacked in layers on the substrate according to their weights, where the larger the weight of a hollow nanosphere, the closer it is to the substrate; heating the hollow nano-spheres so that the hollow nanospheres sublime, and the light-emitting materials in the hollow nanospheres of different weights are stacked and distributed in layers on the substrate; forming a light-emitting element. The hollow nanospheres of an equal weight are filled with an identical light-emitting material, and the hollow nanospheres of different weights are filled with different light-emitting materials. The light-emitting materials are each an organic light-emitting material.

### CROSS-REFERENCE TO RELATED APPLICATIONS

This application claims the priority and benefit of Chinese patent application number 2023114701862, titled “Method for Manufacturing Light-emitting Element, Method for Manufacturing Display Panel, and Display Panel” and filed Nov. 7, 2023 with China National Intellectual Property Administration, the entire contents of which are incorporated herein by reference.

### TECHNICAL FIELD

This application relates to the field of display technology, and more particularly relates to a method for manufacturing a method for manufacturing a light-emitting element, a method for manufacturing a display panel, and a display pane.

### BACKGROUND

The description provided in this section is intended for the mere purpose of providing background information related to the present application but doesn't necessarily constitute prior art.

Organic light emitting diodes (OLEDs) have the advantages of surface light source, cold light, energy saving, fast response, flexibility, ultra-thinness, and low cost. Furthermore, their mass production technology is becoming increasingly mature. The light-emitting element of OLED may be composed of thin films of three luminous colors, RGB, and a patterning process is required in the process of preparing the luminous thin films of the three colors. As a non-contact patterning technology, inkjet printing can directly pattern ink droplets at designated locations on a substrate. Another method is forming a light-emitting element by mask evaporation.

However, the light-emitting element in the OLED device has many film layers, including at least a hole injection layer, a hole transport layer, a light-emitting layer, an electron transport layer, and electron injection layer. Whether the inkjet printing or mask evaporation is used, each film layer needs to be prepared before the next film layer can be prepared, resulting in low preparation efficiency of the light-emitting elements and affecting the delivery speed of display panels. Therefore, how to improve the efficiency of the film-forming process of OLED light-emitting elements is crucial.

### SUMMARY

It is therefore one purpose of this application to provide a method for manufacturing a light-emitting element, a method for manufacturing a display panel, and a display panel to improve the efficiency of the-film forming process of the light-emitting element and improve the production efficiency of the display panel.

The present application discloses a method for manufacturing a light-emitting element, includes:
forming nano hollow spheres of various weights, wherein the nano hollow spheres are filled with light-emitting materials;
placing the hollow nanospheres of various weights on a substrate;
performing screening to stack the hollow nanospheres of various weights in layers on a substrate according to their weights, and the larger the weight, the closer to the substrate;
heating the hollow nanospheres of various weights to sublime the hollow nanospheres, and the light-emitting materials in the hollow nanospheres of different weights are stacked and distributed in layers on the substrate to form a light-emitting element;
where the hollow nanospheres of the same weight are filled with the same light-emitting material, and the hollow nanospheres of different weights are filled with different light-emitting materials; the light-emitting material is an organic light-emitting material.

In some embodiments, the hollow nanospheres are formed of an iodine material.

In some embodiments, the radial widths of hollow nanospheres of various weights are the same. The hollow sizes of hollow nanospheres of various weights are different. The larger the hollow width of the hollow nanosphere, the heavier the hollow nanosphere is after being filled with light-emitting material.

In some embodiments, the radial width of the hollow nanosphere is greater than or equal to 50 nm and less than or equal to 500 nm. A hollow size of the nano hollow sphere is greater than or equal to 10 nm and less than or equal to 490 nm.

In some embodiments, the hollow nanospheres of various weights include a first nanosphere, a second nanosphere, a third nanosphere, a fourth nanosphere, and a fifth nanosphere whose hollow widths decrease in sequence. The shell thickness of the first nanosphere, the shell thickness of the second nanosphere, the shell thickness of the third nanosphere, the shell thickness of the fourth nanosphere, and the shell thickness of the fifth nanosphere increase in sequence. The light-emitting materials include a hole transport layer material, a compensation layer material, a light-emitting layer material, an electron blocking layer material, and an electron transport layer material. The hole transport layer material is filled in the first nanosphere. The compensation layer material is filled in the second nanosphere. The light-emitting layer material is filled in the third nanosphere. The electron blocking layer material is filled in the fourth nanosphere. The electron transport layer material is filled in the fifth nanosphere.

In some embodiments, the operation of placing the hollow nanospheres of various weights on a substrate includes:
forming a bottom electrode on the substrate;
forming an isolation layer on the bottom electrode, forming a plurality of pixel openings on the isolation layer, and exposing the bottom electrode from the pixel openings.

In the step of performing screening so that the hollow nanospheres of various weights are stacked in layers on the substrate according to their weights and that the larger the weight, the closer to the substrate, a solvent is used to screen the hollow nanospheres of various weights, and the heavier the hollow nanospheres, the faster they sink in the solvent;

The step of forming the light-emitting element includes forming a top electrode to form the light-emitting element.

In some embodiments, the operation of performing screening to stack the hollow nanospheres of various weights in layers on a substrate according to their weights and that the larger the weight the closer to the substrate includes:
placing hollow nanospheres of various weights in a solvent;
the hollow nanospheres of various weights descend in the solvent to form multiple layers of hollow nanospheres, each layer of which has the same weight;
removing the solvent to obtain hollow nanospheres arranged in layers.

In some embodiments, the step of heating the hollow nanospheres of the various weights thus sublimating the hollow nanospheres and forming multiple light-emitting material layers on the substrate includes:
heating the substrate to a preset temperature;
the hollow nanospheres closer to the substrate sublimating first, and the hollow nanospheres in the direction away from the substrate gradually sublimating;
forming a light-emitting material layer with a multi-layer stacking arrangement.

The present application further discloses a method for manufacturing a display panel, comprising:
manufacturing a light-emitting element according to the above-mentioned method for manufacturing a light-emitting element;
forming an encapsulation layer;
forming a display panel.

The present application further discloses a display device, including a display panel formed by the above-mentioned manufacturing method.

In the present application, the multiple layers of light-emitting materials in the light-emitting element are respectively filled into hollow nanospheres of different weights. In the step of forming a multi-layer light-emitting material layer, different light-emitting materials can be separated from each other by weight screening. Thus, it is possible to realize the simultaneous inkjet printing of multiple light-emitting material layers. After screening, a multi-layered structure composed of multiple light-emitting material layer can be formed. Compared with the technical solution of forming the various film layer in the light-emitting element layer by layer through inkjet printing in the related technology, the present application forms multiple film layers in the light-emitting element through a one-step process, thereby simplifying the process, saving the time of the manufacturing process of the light-emitting elements, and thus improving the production efficiency of the light-emitting elements and the production efficiency of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a flowchart of a method for manufacturing a light-emitting element according to the present application.

FIG. 2 is a process of heating and sublimating hollow nanospheres according to the present application.

FIG. 3 is a schematic diagram of hollow nanospheres of various weights according to the present application.

FIG. 4 is a schematic diagram of preparing a light-emitting element according to the present application.

FIG. 5 illustrates a method for manufacturing the display panel according to the present application.

In the drawings: 100, light-emitting element; 100a, film particle; 101, hole injection layer; 102, hole transport layer; 103, light-emitting layer; 104, electron transport layer; 105, electron injection layer; 110, bottom electrode; 111, top electrode; 112, isolation column; 200, hollow nanosphere; 201, first nanosphere; 202, second nanosphere; 203, third nanosphere; 204, fourth nanosphere; 205, fifth nanosphere.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

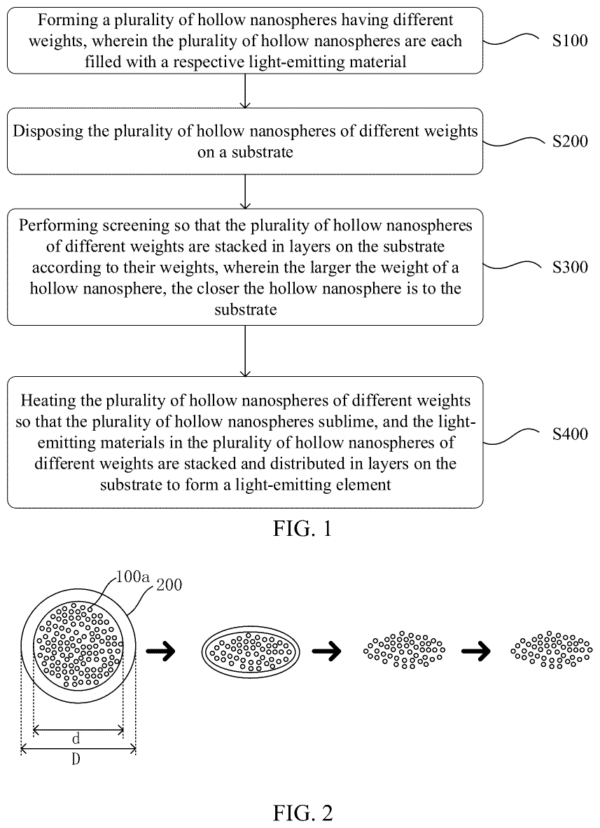

FIG. 1 is a flowchart of a method for making a light-emitting element according to the present application. As shown in FIG. 1, the present application discloses a method for making a light-emitting element, including the following operations:
S100: forming hollow nanospheres of various weights, wherein the hollow nanospheres are each filled with a light-emitting material;
S200: placing the hollow nanospheres of various weights on a substrate;
S300: performing screening to stack the hollow nanospheres of various weights on a substrate in layers according to their weights, and the larger the weight, the closer to the substrate;
S400: heating the hollow nanospheres of various weights so that the hollow nanospheres are sublimated, and the light-emitting materials in the hollow nanospheres of different weights are stacked and distributed in layers on the substrate to form a light-emitting element;
where the hollow nanospheres of the same weight are filled with the same light-emitting material, and the hollow nanospheres of different weights are filled with different light-emitting materials; the light-emitting material is an organic light-emitting material.

In the present application, the multiple layers of light-emitting materials in the light-emitting element are respectively filled into hollow nanospheres of different weights. In the step of forming a multi-layer light-emitting material layer, different light-emitting materials can be separated from each other by weight screening. Thus, it is possible to realize the simultaneous inkjet printing of multiple light-emitting material layers. After screening, a multi-layered structure composed of multiple light-emitting material layer can be formed. Compared with the technical solution of forming the various film layer in the light-emitting element layer by layer through inkjet printing in the related technology, the present application forms multiple film layers in the light-emitting element through a one-step process, thereby simplifying the process, saving the time of the manufacturing process of the light-emitting elements, and thus improving the production efficiency of the light-emitting elements and the production efficiency of the display panel.

In this embodiment, hollow nanospheres of different weights are filled with different light-emitting materials. Through weight screening, hollow nanospheres of different weights are screened out to form multiple film layers in the light-emitting element respectively.

As a non-contact patterning technology, inkjet printing can directly pattern ink droplets at designated locations on a substrate. Inkjet printing first melts the light-emitting material in a solvent to make it into an ink shape. The ink containing the light-emitting material is sprayed onto the substrate through a nozzle of an inkjet head, and printed between the gratings of the substrate. Finally, after the solvent is removed through the drying process, the printing of OLED materials is completed. Due to the technical characteristics of inkjet printing, each functional layer needs to be sprayed separately, and has to be dried before the next layer can be prepared. It can be understood that since the materials of each film layer in the light-emitting element are different, in the related technology, each time a layer is printed with inkjet, it needs to go through processes such as loading, spraying, and drying to complete the production of a film layer. Moreover, when forming the next film layer, the inkjet device needs to be replaced, which is extremely time-consuming. For the Tandem OLED technology route with multiple layers of luminescent materials, the preparation efficiency is extremely low, and the spraying precision in inkjet printing is also required to be extremely high.

In this application, film particles formed by different layers of light-emitting materials in the light-emitting element are wrapped in nanospheres of different weights. Using the screening structure, hollow nanospheres of different weights are screened and deposited so that they can be deposited in the required films stacking sequence. After the stacking of nanospheres in all film layers is completed, heating is performed to directly sublimate the nanospheres. The film particles wrapped inside will be released and form a film evenly, which can significantly increase the film formation rate of the organic light-emitting layer.

In S100, the preparation of the hollow nanosphere can use an ultrasonic chemical method, a hydrothermal method or a template method. In this step, the preparation of the hollow nanospheres and light-emitting materials can be completed in the material factory before they are directly transported to the panel factory, or directly produced in the panel factory. This application separates the preparation of hollow nanosphere from the process of display panel, and the two can be carried out simultaneously, further reducing the process time of the display panel.

Specifically, the hollow nanosphere is formed by an iodine material. Iodine can start to sublimate at a temperature of about 45 degrees and can be completely sublimated at about 77 degrees. In this embodiment, iodine material is selected as the material of hollow nanosphere. In the subsequent processes, the hollow nanosphere can be completely removed by heating to an appropriate temperature, leaving only the membrane layer particle to form a membrane layer. The process in which a solid substance evaporates directly into steam without going through a liquid process is called “sublimation”. Sublimation is an endothermic process. Sublimation may occur on the surface of any solid at room temperature and pressure. Iodine is a solid substance at room temperature and sublimates under slight heat. Iodine has low chemical activity and may not react with metals. It is worth mentioning that the hollow nanosphere of the present application includes but is not limited to iodine materials, and other materials with the same sublimation characteristics are also applicable to the present application.

FIG. 2 is a schematic diagram illustrating a heating sublimation process of a hollow nanosphere according to the present application. As shown in FIG. 2, the hollow nanosphere is spherical before heating. After gradual heating, the hollow nanosphere gradually ellipsoidizes until the hollow nanosphere is completely sublimated. The membrane layer particles of the light-emitting material inside the hollow nanosphere is dispersed from the hollow nanosphere to form a light-emitting material layer. During the sublimation process, the spherical shape will deform as the spherical material sublimates. The thickness of the sphere gradually decreases, and the shape gradually becomes elliptical or flat. During the shape change process, the membrane layer particles contained in the sphere will also be redistributed along with the change of the spherical shape, and finally a flattening effect may be presented. After the sphere sublimates, the membrane layer particles will remain to form a film.

Continuing to refer to FIG. 2, the radial width of the hollow nanosphere 200 is greater than or equal to 50 nm and less than or equal to 500 nm. The radial width D of the hollow nanosphere 200 in this application refers to the particle size of the hollow nanosphere. The hollow nanosphere 200 is provided with an inner cavity, and the size of the inner cavity is the hollow size d, which affects the number and weight of the film particles 100a filled with the light-emitting material. Specifically, the hollow size of the hollow nanosphere is greater than or equal to 10 nm and less than or equal to 490 nm. Of course, the above range is when the radial width of the hollow nanosphere is between 50 nm and 500 nm. When the radial width of the hollow nanosphere is 100 nm, the hollow width of the hollow nanosphere is between 10 nm and 90 nm (including the end values). In other words, the shell thickness of the hollow nanosphere is at least 10 nm, so that the hollow nanosphere has a certain strength to prevent the light-emitting material filled inside from breaking. Moreover, the hollow width of the hollow nanosphere should not be too low. If it is too low, the number of film particles filled will be affected, and the gap between film particles will be too large during the sublimation process of the hollow nanosphere. Correspondingly, the hollow width of the hollow nanosphere is not less than the radial width of the hollow nanosphere.

In a specific embodiment, different light-emitting materials are filled in hollow nanospheres of different weights. Specifically, the hollow sizes of the hollow nanospheres are different, so the weights of the light-emitting materials placed are different, and different film layers have different weights.

The radial widths of hollow nanospheres of various weights are the same. The hollow sizes of hollow nanospheres of various weights are different. The larger the hollow width of the hollow nanosphere, the heavier the hollow nanosphere is after being filled with light-emitting material.

In this solution, the different weights of hollow nanospheres have different falling speeds in the solvent, thus forming multiple layers of hollow nanospheres of different weights, thereby forming multiple film layers in one step. According to the buoyancy formula F_{buoy}=ρₛₒₗᵥₑₙₜ*g*V, since the volumes of the five hollow nanospheres are the same, their buoyancies are the same. According to the acceleration formula Ma=Mg−F_{buoy}, the acceleration a=g−(F_{buoy}/M). Thus, under the same buoyancy, the larger the mass of the sphere, the greater its acceleration. Correspondingly, under different acceleration conditions, hollow nanospheres of different weights fall from the solvent onto the substrate to form multiple layers of hollow nanospheres arranged in layers. It is worth mentioning that the solvent does not react with the hollow nanosphere, that is, the hollow nanosphere is not soluble in the solvent.

It is understandable that the radial width of each hollow nanosphere in this embodiment does not need to be completely consistent, but they can be roughly the same. For example, if the difference in radial widths between different hollow nanospheres is within 10 nm, then the difference in size can be simply ignored. Therefore, the radial widths of the corresponding multiple hollow nanospheres are not exactly the same, and the difference in size is within a controllable range, which also falls in the scope of protection of this application.

In another embodiment, the radial width of each hollow nanosphere can be set to be different, while the shell thickness of each hollow nanosphere may be the same. Correspondingly, the larger the radial width of the hollow nanosphere, the larger the hollow size of the hollow nanosphere, the more film particles filled inside, and the heavier the weight of the corresponding hollow nanosphere.

In this solution, different light-emitting materials can also be distinguished by judging the radial widths of the hollow nanospheres. The thickness of each film layer in the light-emitting element may be in the micron level. Correspondingly, in a film layer, a large number of hollow nanospheres are required for filling, and before the hollow nanospheres are sublimated, the formed films have a certain degree of flatness. Even after the hollow nanospheres are sublimated, the interface between the film layers can be guaranteed.

Specifically, the radial widths of the hollow nanospheres can be screened by using a molecular sieve structure. The molecular sieve structure can use a variety of molecular sieve membranes with different screening sizes. In this embodiment, when hollow nanospheres are subsequently screened using screening structures such as a molecular sieve, the minimum size difference between hollow nanospheres of different sizes is still 50 nm, so that the subsequent molecular sieve can better distinguish hollow nanospheres of different sizes.

The display principle of OLED (Organic Light Emitting Diode) is simply the phenomenon of luminescence caused by carrier injection and recombination under the drive of an electric field. The principle is using an ITO transparent electrode and a metal electrode as the top electrode and bottom electrode of the device respectively. Under the drive of a certain voltage, electrons and holes are respectively injected from the top electrode and bottom electrode through the electron injection layer (EIL) and the hole injection layer (HIL) into the electron transport layer (ETL) and the hole transport layer (HTL), and then migrate to the emission layer (EML), where they meet to form excitons to excite the luminescent molecules, which emit visible light after radiation.

This application takes the five-layer film structure in the above-mentioned light-emitting element as an example for explanation. It can be understood that in actual situations, the size of the hollow nanosphere that can be designed in this application can vary with the number of film layers.

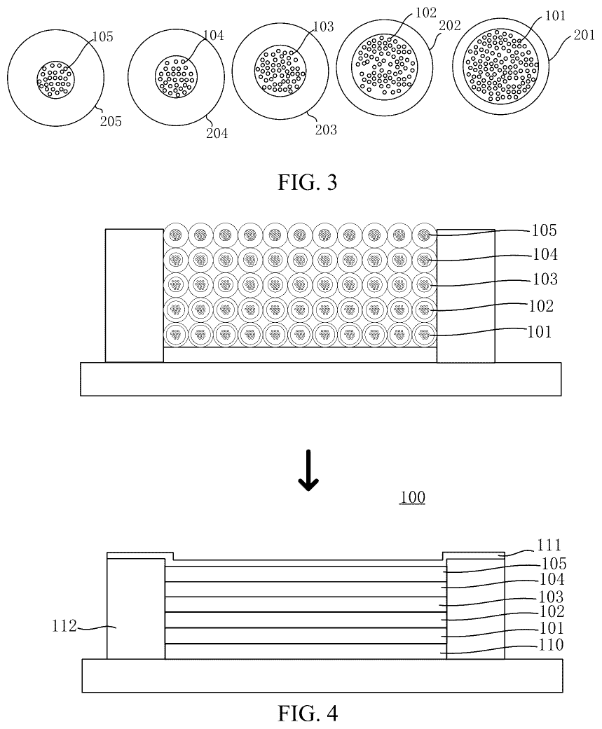

FIG. 3 is a schematic diagram of hollow nanospheres of various weights according to the present application. As shown in FIG. 3, the radial widths D of the hollow nanospheres 200 of various weights are all the same, but the hollow widths d are different. The hollow width d is the width of the inner cavity of the hollow nanosphere. The sum of the hollow width and twice the shell thickness is the radial width of the hollow nanosphere. In this solution, the hollow nanospheres 200 include a first nanosphere 201, a second nanosphere 202, a third nanosphere 203, a fourth nanosphere 204, and a fifth nanosphere 205 in a descending order of the hollow widths. When the radial widths of the hollow nanospheres are consistent, the shell thickness of the first nanosphere 201, the shell thickness of the second nanosphere 202, the shell thickness of the third nanosphere 203, the shell thickness of the fourth nanosphere 204, and the shell thickness of the fifth nanosphere 205 increase in sequence. As such, after each hollow nanosphere is filled with film particles 100a, the weight of the first nanosphere 201 is greater than the weight of the second nanosphere 202, the weight of the second nanosphere 202 is greater than the weight of the third nanosphere 203, the weight of the third nanosphere 203 is greater than the weight of the fourth nanosphere 204, and the weight of the fourth nanosphere 204 is greater than the weight of the fifth nanosphere 205.

Specifically, the hollow nanospheres are filled with the various film particles 100a of the light-emitting element. The light-emitting element 100 materials include a hole injection layer 101 material, a hole transport layer 102 material, a light-emitting layer 103 material, an electron transport layer 104 material, and an electron injection layer 105 material. The above materials are all made into film particles 100a of the same size. The hole injection layer 101 material is filled in the first nanosphere 201. The hole transport layer 102 material is filled in the second nanosphere 202. The light-emitting layer 103 material is filled in the third nanosphere 203. The electron transport layer 104 material is filled in the fourth nanosphere 204. The electron injection layer 105 material is filled in the fifth nanosphere 205.

Specifically, S200 includes:
S210: forming a bottom electrode on a substrate;
S211: forming an isolation layer on the bottom electrode, forming a plurality of pixel openings on the isolation layer, and exposing the bottom electrode from the pixel openings.

In step S300, a solvent is used to screen hollow nanospheres of various weights, and the heavier a hollow nanosphere is, the faster it sinks in the solvent.

In step S400, a top electrode is formed on the light-emitting material layer to form a light-emitting element.

In this embodiment, the weight screening method is mainly used to screen hollow nanospheres of various weights to form film particles arranged in multiple layers.

FIG. 4 is a schematic diagram of manufacturing a light-emitting element according to the present application. As shown in FIG. 4, a bottom electrode 110 is disposed on the substrate. Isolation columns 112 are disposed on both sides of the bottom electrode 110. The isolation columns form a pixel opening in the opening area and exposes the bottom electrode by patterning the isolation layer. The isolation layer is retained in a non-opening area to form the isolation columns 112. A solvent is disposed in the pixel opening area, which can be a solvent used in inkjet printing and can be removed through the process subsequently. The five hollow nanospheres of different weights descend at different speeds in the solvent because different gravities produce different deposition speeds. That is, the first nanosphere 201 forms a film layer at the bottom. The second nanosphere 202 is located on the first nanosphere 201. The third nanosphere 203 is located on the second nanosphere 202. The fourth nanosphere 204 is located on the third nanosphere 203. The fifth nanosphere 205 is located on the fourth nanosphere 204. Relatively speaking, the size of each hollow nanosphere is relatively small, and a relatively flat film layer can be formed during the layering process. That is, a hole injection layer 101, a hole transport layer 102, a light-emitting layer 103, an electron transport layer 104, and an electron injection layer 105 are formed on the bottom electrode 110, and finally a top electrode 111 is formed on the electron injection layer 105 and the isolation columns 112.

The step S300 includes:
S301: placing hollow nanospheres of various weights in a solvent;
S302: the hollow nanospheres of various weights descend in the solvent to form multiple layers of hollow nanospheres, each layer of which has the same weight;
S303: removing the solvent to obtain hollow nanospheres arranged in layers.

In this solution, a solvent is placed at the position of each pixel opening. Then hollow nanospheres of various weights are placed in the solvent. Due to different deposition speeds, a multiple layers of hollow nanospheres are formed, and the weight of the hollow nanospheres in each layer is consistent.

Specifically, in this solution, all hollow nanospheres can be put into the solvent at the same time, or the first nanosphere, second nanosphere, third nanosphere, fourth nanosphere, and fifth nanosphere can be placed into the solvent in batches by calculating the weights. In this solution, even if the deposition is carried out in batches, relatively speaking, the solvent can be altogether removed in the last step, and the hollow nanosphere can be heated and sublimated to form a multiple layers of films. Compared with the solution of inkjet printing, which requires the removal of solvent and thermoforming at each step, it saves time and improves efficiency.

In another embodiment, hollow nanospheres of various weights may be pre-treated, that is, before being disposed at the pixel openings, the hollow nanospheres of various weights may be slightly shaken. Before deposition, the hollow nanospheres of various weights have a preset layering, so that even if placed in the solvent of the pixel openings, the hollow nanospheres of various weights may be arranged according to the preset layering to form multiple film layers.

Specifically, S400 includes:
S401: heating the substrate to a preset temperature;
S402: the hollow nanospheres closer to the substrate sublimate first, and

the hollow nanospheres in the direction facing away from the substrate gradually sublimate;
S403: forming a light-emitting material layer with a multi-layer stacking arrangement.

In this embodiment, the sublimation speed of the hollow nanospheres is related to the heating speed. The faster the heating, the faster the corresponding hollow nanosphere sublimates. In this solution, heating is performed on one side of the substrate. It takes a certain amount of time for heat to be transferred, that is, it takes a certain amount of time for the hole injection layer on the substrate to be transferred to the electron injection layer. Therefore, the heat will be transferred to the hole injection layer first, and after the hollow nanosphere of the hole injection layer breaks and sublimates, the heat will gradually be transferred to the hole transport layer. Moreover, the hollow nanospheres of the hole injection layer absorb heat during sublimation and delay the time for the heat to reach the hole transport layer, so that after the hollow nanospheres of the hole injection layer are completely sublimated, the heat continues to enter the hollow transport layer. Through the above process, the hole injection layer, the hole transport layer, the light-emitting layer, electron transport layer, and the electron injection layer in the light-emitting element can be made, which can be completed without a high temperature, and the performance of the light-emitting element is not affected at all.

In this embodiment, the shell thickness of the hollow nanosphere gradually increases from the first nanosphere to the fifth nanosphere on the substrate. When the substrate is heated, the first nanosphere receives the heat of the substrate first, and the shell thickness of the first nanosphere is the thinnest, so it breaks first. The shell of the second nanosphere is thicker than that of the first nanosphere and is farther from the heat source. Therefore, after the first nanosphere is completely sublimated, the second nanosphere gradually sublimates, avoiding the mutual invasion of film particles between adjacent layers. When the first nanosphere is sublimated, the sublimation gas will be discharged from the gaps between the second nanosphere, third nanosphere, fourth nanosphere, and fifth nanosphere above, thereby improving the sublimation efficiency. At the same time, the pinholes in the film layers caused by sublimation are avoided, and the density of the film layers can be improved by proceeding upward in sequence.

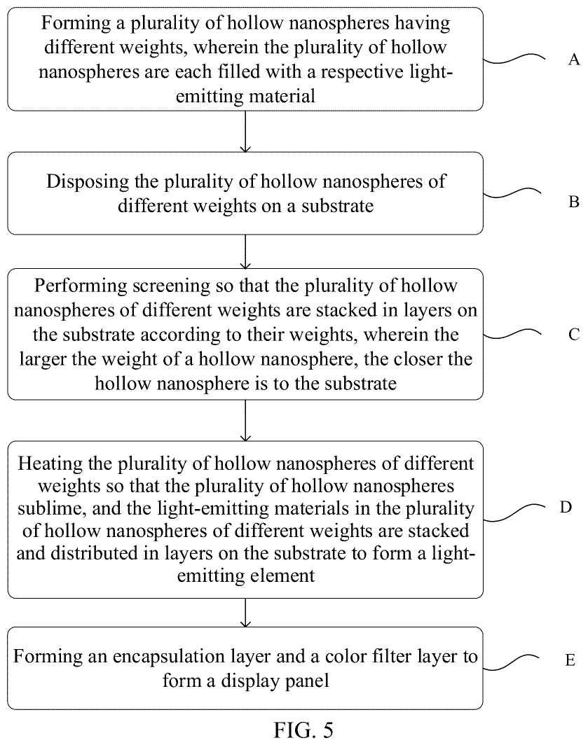

FIG. 5 is a flowchart of a method for manufacturing a display panel according to the present application. As shown in FIG. 5, the present application discloses a method for making a display panel, including:
A: forming hollow nanospheres of various weights, wherein the hollow nanospheres are filled with light-emitting materials;
B: placing the hollow nanospheres of various weights on a substrate;
C: performing screening to stack the hollow nanospheres of various weights in layers on a substrate according to their weights, and the larger the weight, the closer to the substrate;
D: heating the hollow nanospheres of various weights to sublime the hollow nanospheres, and the light-emitting materials in the hollow nanospheres of different weights are stacked and distributed in layers on the substrate to form a light-emitting element;
E: forming an encapsulation layer and a color filter layer to form a display panel.

Correspondingly, the present application further discloses a display device, including a display panel formed by the above-mentioned manufacturing method.

In the present application, the multiple layers of light-emitting materials in the light-emitting element are respectively filled into hollow nanospheres of different weights. In the step of forming a multi-layer light-emitting material layer, different light-emitting materials can be separated from each other by weight screening. Thus, it is possible to realize the simultaneous inkjet printing of multiple light-emitting material layers. After screening, a multi-layered structure composed of multiple light-emitting material layer can be formed. Compared with the technical solution of forming the various film layer in the light-emitting element layer by layer through inkjet printing in the related technology, the present application forms multiple film layers in the light-emitting element through a one-step process, thereby simplifying the process, saving the time of the manufacturing process of the light-emitting elements, and thus improving the production efficiency of the light-emitting elements and the production efficiency of the display panel.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A method for manufacturing a light-emitting element, comprising:
forming a plurality of hollow nanospheres having different weights, wherein the plurality of hollow nanospheres are each filled with a respective light-emitting material;
disposing the plurality of hollow nanospheres of different weights on a substrate;
performing screening so that the plurality of hollow nanospheres of different weights are stacked in layers on the substrate according to their weights, wherein the larger the weight of a hollow nanosphere, the closer the hollow nanosphere is to the substrate;
heating the plurality of hollow nanospheres of different weights so that the plurality of hollow nanospheres sublime, and the light-emitting materials in the plurality of hollow nanospheres of different weights are stacked and distributed in layers on the substrate to form a light-emitting element;
wherein the hollow nanospheres of an equal weight are filled with an identical light-emitting material, and wherein the hollow nanospheres of different weights are filled with different light-emitting materials; wherein the light-emitting materials are each an organic light-emitting material.

2. The method as recited in claim 1, wherein the plurality of hollow nanospheres are each formed of an iodine material.

3. The method as recited in claim 1, wherein the plurality of hollow nanospheres of different weights have an equal radial width;
wherein the plurality of hollow nanospheres of different weights have different hollow sizes, wherein the larger a hollow width of a hollow nanosphere, the heavier the hollow nanosphere is after being filled with the respective light-emitting material.

4. The method as recited in claim 3, wherein each of the plurality of hollow nanospheres has a radial width that is greater than or equal to 50 nm and less than or equal to 500 nm;
wherein each of the plurality of hollow nanospheres has a hollow size that is greater than or equal to 10 nm and less than or equal to 490 nm.

5. The method as recited in claim 1, wherein the plurality of hollow nanospheres of different weights comprise a first nanosphere, a second nanosphere, a third nanosphere, a fourth nanosphere, and a fifth nanosphere, whose hollow widths decrease in sequence;
wherein a shell thickness of the first nanosphere, a shell thickness of the second nanosphere, a shell thickness of the third nanosphere, a shell thickness of the fourth nanosphere, and a shell thickness of the fifth nanosphere increase in sequence;
wherein the light-emitting materials in the plurality of hollow nanospheres of different weights comprise a hole transport layer material, a compensation layer material, a light-emitting layer material, an electron blocking layer material, and an electron transport layer material;
wherein the hole transport layer material is filled in the first nanosphere; wherein the compensation layer material is filled in the second nanosphere; wherein the light-emitting layer material is filled in the third nanosphere; wherein the electron blocking layer material is filled in the fourth nanosphere; wherein the electron transport layer material is filled in the fifth nanosphere.

6. The method as recited in claim 5, wherein the operation of disposing the plurality of hollow nanospheres of different weights on the substrate comprises:
forming a bottom electrode on the substrate;
forming an isolation layer on the bottom electrode, defining a plurality of pixel openings in the isolation layer, and exposing the bottom electrode from the plurality of pixel openings;
wherein in the operation of performing screening so that the plurality of hollow nanospheres of different weights are stacked in layers on the substrate according to their weights, the plurality of hollow nanospheres of different weights are screened by a solvent, wherein the heavier a hollow nanosphere is, the faster the hollow nanosphere sinks in the solvent;
wherein the operation of forming the light-emitting element comprises forming a top electrode to form the light-emitting element.

7. The method as recited in claim 6, wherein the operation of performing screening so that the plurality of hollow nanospheres of different weights are stacked in layers on the substrate according to their weights comprises:
placing the plurality of hollow nanospheres of different weights in a solvent and allowing the plurality of hollow nanospheres of different weights to descend in the solvent to form a plurality of layers of nanospheres, wherein each layer of hollow nanospheres has an equal weight; and
removing the solvent to obtain the plurality of hollow nanosphere that are arranged in layers.

8. The method as recited in claim 7, wherein the operation of placing the plurality of hollow nanospheres of different weights in the solvent comprises:
placing all the plurality of hollow nanospheres in the solvent simultaneously, or placing the first nanosphere, the second nanosphere, the third nanosphere, the fourth nanosphere, and the fifth nanosphere in the solvent in batches.

9. The method as recited in claim 7, further comprising the following operations subsequent to the operation of placing the plurality of hollow nanospheres of different weights in the solvent:
slightly shaking the plurality of hollow nanospheres of different weights so that the plurality of hollow nanospheres of different weights have a preset layering prior to deposition.

10. The method as recited in claim 1, wherein the operation of heating the plurality of hollow nanospheres of different weights so that the plurality of hollow nanospheres sublimate and the light-emitting materials in the plurality of hollow nanospheres of different weights are stacked and distributed in layers on the substrate comprises:
heating the substrate to a preset temperature, wherein each hollow nanosphere comparatively closer to the substrate sublimes earlier than each another hollow nanosphere comparatively farther away from the substrate; and
forming a plurality of light-emitting material layers that are stacked in layers on the substrate.

11. A method for manufacturing a display panel, comprising:
forming a plurality of hollow nanospheres of different weights, wherein the plurality of hollow nanospheres are each filled with a respective light-emitting material;
disposing the plurality of hollow nanospheres of different weights on a substrate;
performing screening so that the plurality of hollow nanospheres of different weights are stacked in layers on the substrate according to their weights, wherein the larger the weight of a hollow nanosphere, the closer the hollow nanosphere is to the substrate;
heating the plurality of hollow nanospheres of different weights so that the plurality of hollow nanospheres sublime, and the light-emitting materials in the plurality of hollow nanospheres of different weights are stacked and distributed in layers on the substrate to form a light-emitting element;
forming an encapsulation layer and a color filter layer to form a display panel;
wherein the hollow nanospheres of an equal weight are filled with an identical light-emitting material, and wherein the hollow nanospheres of different weights are filled with different light-emitting materials; wherein the light-emitting materials are each an organic light-emitting material.

12. The method as recited in claim 11, wherein the plurality of hollow nanospheres are each formed of an iodine material.

13. The method as recited in claim 11, wherein the plurality of hollow nanospheres of different weights have an equal radial width;
wherein the plurality of hollow nanospheres of different weights have different hollow sizes, wherein the larger a hollow width of a hollow nanosphere, the heavier the hollow nanosphere is after being filled with the respective light-emitting material.

14. The method as recited in claim 13, wherein each of the plurality of hollow nanospheres has a radial width that is greater than or equal to 50 nm and less than or equal to 500 nm;
wherein each of the plurality of hollow nanospheres has a hollow size that is greater than or equal to 10 nm and less than or equal to 490 nm.

15. The method as recited in claim 11, wherein the plurality of hollow nanospheres of different weights comprise a first nanosphere, a second nanosphere, a third nanosphere, a fourth nanosphere, and a fifth nanosphere, whose hollow widths decrease in sequence;
wherein a shell thickness of the first nanosphere, a shell thickness of the second nanosphere, a shell thickness of the third nanosphere, a shell thickness of the fourth nanosphere, and a shell thickness of the fifth nanosphere increase in sequence;
wherein the light-emitting materials in the plurality of hollow nanospheres of different weights comprise a hole transport layer material, a compensation layer material, a light-emitting layer material, an electron blocking layer material, and an electron transport layer material;
wherein the hole transport layer material is filled in the first nanosphere; wherein the compensation layer material is filled in the second nanosphere; wherein the light-emitting layer material is filled in the third nanosphere; wherein the electron blocking layer material is filled in the fourth nanosphere; wherein the electron transport layer material is filled in the fifth nanosphere.

16. The method as recited in claim 15, wherein the operation of disposing the plurality of hollow nanospheres of different weights on the substrate comprises:
forming a bottom electrode on the substrate;
forming an isolation layer on the bottom electrode, defining a plurality of pixel openings in the isolation layer, and exposing the bottom electrode from the plurality of pixel openings;
wherein in the operation of performing screening so that the plurality of hollow nanospheres of different weights are stacked in layers on the substrate according to their weights, the plurality of hollow nanospheres of different weights are screened by a solvent, wherein the heavier the hollow nanosphere is, the faster the hollow nanosphere sinks in the solvent;
wherein the operation of forming the light-emitting element comprises forming a top electrode to form the light-emitting element.

17. The method as recited in claim 16, wherein the operation of performing screening so that the plurality of hollow nanospheres of different weights are stacked in layers on the substrate according to their weights comprises:
placing the plurality of hollow nanospheres of different weights in a solvent and allowing the plurality of hollow nanospheres of different weights to descend in the solvent to form a plurality of layers of nanospheres, wherein each layer of hollow nanospheres has an equal weight;
and removing the solvent to obtain a plurality of hollow nanosphere arranged in layers.

18. A display panel, comprising a light-emitting element formed by a method for manufacturing a light-emitting element, the method comprising:
forming a plurality of hollow nanospheres of different weights, wherein the plurality of hollow nanospheres are each filled with a respective light-emitting material;
disposing the plurality of hollow nanospheres of different weights on a substrate;
performing screening so that the plurality of hollow nanospheres of different weights are stacked in layers on the substrate according to their weights, wherein the larger the weight of a hollow nanosphere, the closer the hollow nanosphere is to the substrate;
heating the plurality of hollow nanospheres of different weights so that the plurality of hollow nanospheres sublime, and the light-emitting materials in the plurality of hollow nanospheres of different weights are stacked and distributed in layers on the substrate to form a light-emitting element;
wherein the hollow nanospheres of an equal weight are filled with an identical light-emitting material, and wherein the hollow nanospheres of different weights are filled with different light-emitting materials; wherein the light-emitting materials are each an organic light-emitting material.
